(19) United States
(12) Patent Application Publication
(10) Pub. No.: US 2026/0282838 A1
(43) Pub. Date: Sep. 17, 2026

(54) CHUCK PIN, SUBSTRATE HOLDING DEVICE, AND SUBSTRATE PROCESSING DEVICE

(71) Applicant: SCREEN Holdings Co., Ltd., Kyoto (JP)

(72) Inventor: Takashi SHINOHARA, Kyoto (JP)

(73) Assignee: SCREEN Holdings Co., Ltd., Kyoto (JP)

(21) Appl. No.: 19/393,571

(22) Filed: Nov. 19, 2025

(30) Foreign Application Priority Data
Mar. 12, 2025 (JP) 2025-039587

(51) Int. Cl. H10P 72/76; H10P 72/00

(52) U.S. Cl. CPC H10P 72/7618; H10P 72/0408; H10P 72/0412; H10P 72/0414

(57) ABSTRACT

A chuck pin is provided on a base part rotating around a reference axis extending in an up-down direction and holding a substrate that is disposed above the base part, the substrate being subjected to processing by a processing liquid. The check pin includes: a main body part having a main surface at an upper portion; a lower surface support part that is provided to protrude upward from the main surface and that supports a lower surface of the substrate; and a side surface grip part that is provided to protrude upward from the main surface while being separated from the lower surface support part and that grips a side surface of the substrate.

### CROSS-REFERENCE TO RELATED APPLICATION

This application claims the priority benefits of Japanese application no. 2025-039587, filed on March 12, 2025. The entirety of the above-mentioned patent application is hereby incorporated by reference herein and made a part of this specification.

### BACKGROUND

### Technical Field

The disclosure relates to a chuck pin, a substrate holding device, and a substrate processing device.

### Related Art

Patent Document 1 discloses a substrate processing device that performs cleaning processing on a substrate. The substrate processing device holds the substrate substantially horizontally by a spin chuck and performs cleaning. The spin chuck grips the substrate by a plurality of chuck pins.

### Citation List

### Patent Document

[Patent Document 1] Japanese Patent Application Laid-Open Publication No. 2009-206139

However, the device of Patent Document 1 has a problem in that processing liquid for cleaning flows from the contact point between the substrate and the chuck pin along the chuck pin to the back surface of the substrate and remains on the substrate. In this case, problems such as collapse of fine structures such as circuits formed on the back surface of the substrate and generation of particles derived from the processing liquid are caused.

One aspect of the disclosure aims to realize a chuck pin and the like in which processing liquid is less likely to remain on the substrate.

### SUMMARY

A chuck pin according to one aspect of the disclosure is provided on a base part rotating around a reference axis extending in an up-down direction and holding a substrate that is disposed above the base part, the substrate being subjected to processing by a processing liquid, the chuck pin including: a main body part having a main surface at an upper portion; a lower surface support part that is provided to protrude upward from the main surface and that supports a lower surface of the substrate; and a side surface grip part that is provided to protrude upward from the main surface while being separated from the lower surface support part and that grips a side surface of the substrate.

Also, a substrate holding device according to one aspect of the disclosure includes: a base part provided rotatably around a reference axis extending in an up-down direction; a rotator that rotates the base part around the reference axis; any one of the above chuck pins attached to the base part; and a chuck pin drive part. At least one among the plurality of chuck pins is rotatably attached to the base part around a pin shaft parallel to the reference axis, and the chuck pin drive part is configured to be capable of switching the chuck pin between a holding state in which the chuck pin contacts an outer edge of the substrate to hold the substrate and a release state in which the chuck pin is capable of being separated from the outer edge of the substrate, by rotating the rotatable chuck pin around the pin shaft.

### BRIEF DESCRIPTION OF THE DRAWINGS

FIG. 1 is a diagram showing one example of a substrate processing device according to Embodiment 1.

FIG. 2 is a diagram showing one example of a substrate holding device according to Embodiment 1.

FIG. 3 is a block diagram showing a configuration of a control system of the substrate processing device of FIG. 1.

FIG. 4 is a diagram showing an example of a configuration of a fixed chuck pin.

FIG. 5 is a diagram showing an example of a configuration of a movable chuck pin.

FIG. 6 is a diagram for describing a fixed chuck pin, a guide chuck pin, and a movable chuck pin in the case of the substrate holding device gripping a substrate.

FIG. 7 is a diagram showing a flow of processing liquid on an upper surface side of a substrate.

FIG. 8 is a diagram showing a flow of processing liquid on a lower surface side of a substrate.

FIG. 9 is a diagram showing a flow of processing liquid in one example of a substrate holding device of a Comparative Example.

FIG. 10 is a plan view showing a schematic configuration of a substrate processing system equipped with a substrate processing device according to Embodiment 1.

FIG. 11 is a schematic side view showing a configuration of a substrate processing device according to Embodiment 2.

FIG. 12 is a diagram showing a vicinity of a fixed chuck pin in a substrate holding device of a substrate processing device according to Embodiment 2.

FIG. 13 is a diagram showing a vicinity of a movable chuck pin in a substrate holding device of a substrate processing device according to Embodiment 2.

FIG. 14 is a flowchart showing one example of a substrate processing method by a substrate processing system equipped with a substrate processing device according to Embodiment 1.

FIG. 15 is a flowchart showing one example of a substrate processing method by a substrate processing system equipped with a substrate processing device according to Embodiment 2.

### DESCRIPTION OF THE EMBODIMENTS

According to one aspect of the disclosure, a chuck pin and the like in which processing liquid is less likely to remain on the substrate can be realized.

### Embodiment 1

The chuck pin and substrate holding device are used in a substrate processing device. Hereinafter, a substrate processing device including a chuck pin and a substrate holding device according to one embodiment of the disclosure will be described with reference to the drawings.

In the following description, a substrate refers to an FPD (Flat Panel Display) substrate used in liquid crystal display devices or organic EL (Electro Luminescence) display devices, semiconductor substrates, optical disk substrates, magnetic disk substrates, magneto-optical disk substrates, photomask substrates, ceramic substrates, solar cell substrates, or the like. Moreover, the substrate described below is a substrate having at least a partially circular shape, and is a circular substrate having a positioning notch formed in a part of an outer peripheral end.

The substrate in the following description includes two main surfaces and a side surface. The two main surfaces respectively indicate an upper surface that becomes an upper face and a lower surface that becomes a lower face in the case of being held by the substrate holding device and the substrate processing device. The side surface indicates a portion that is substantially perpendicular to a horizontal plane in the case of the substrate being held by the substrate holding device and the substrate processing device. Moreover, the substrate further includes chamfered portions that are chamfered to be inclined between the upper surface and the side surface and between the lower surface and the side surface.

### Substrate processing device

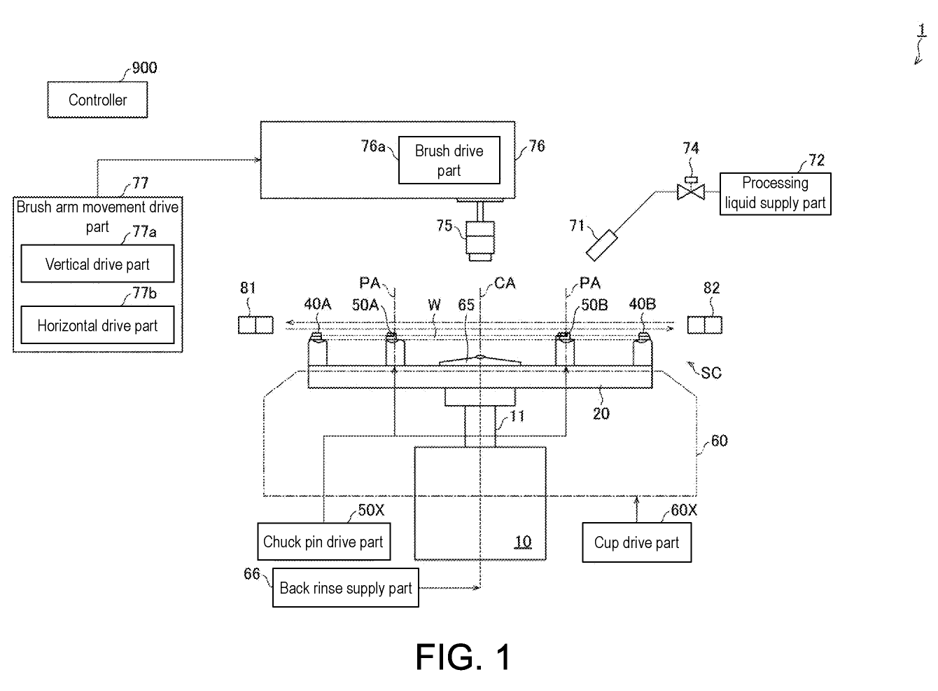

FIG. 1 is a schematic side view showing a basic configuration of a substrate processing device 1. As shown in FIG. 1, the substrate processing device 1 includes a substrate holding device SC, a nozzle 71, and a processing liquid supply part 72. Moreover, the substrate processing device 1 further includes a cup 60, a cup drive part 60X, a back rinse nozzle 65, a back rinse supply part 66, a cleaning brush 75, a swing arm 76, a brush arm movement drive part 77, two substrate sensors (substrate detectors) 81 and 82, and a controller (control part) 900. Each of these components is accommodated in, for example, a chamber not shown.

The substrate holding device SC holds a substrate W. A specific configuration of the substrate holding device SC will be described later.

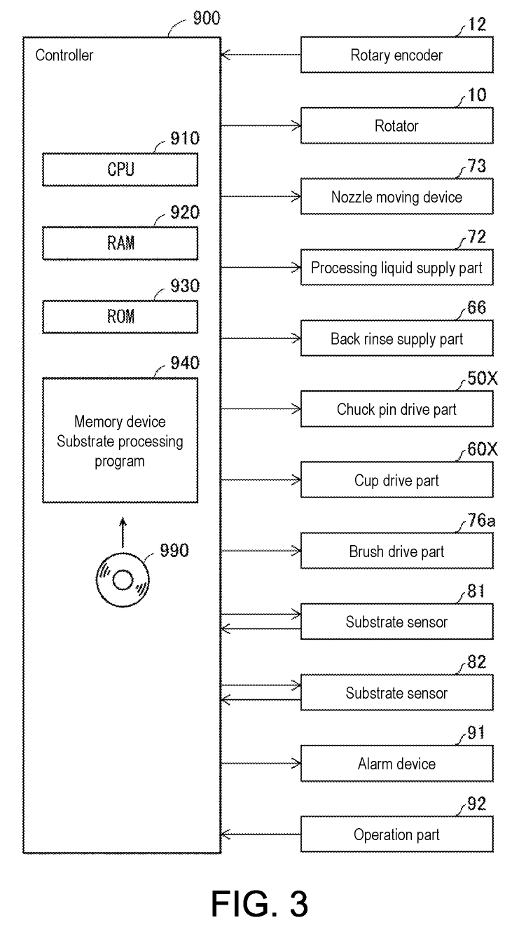

The nozzle 71 supplies processing liquid to an upper surface of the substrate W held by the substrate holding device SC. The nozzle 71 is movably supported between a processing position above the substrate holding device SC and a standby position lateral to the substrate holding device SC within a chamber of the substrate processing device 1 by a nozzle moving device 73 (FIG. 3) described later. In a state where the substrate W is held by the substrate holding device SC and the nozzle 71 is disposed at the processing position, processing liquid is supplied from the processing liquid supply part 72 to the nozzle 71. Thereby, processing liquid is discharged from the nozzle 71 to the substrate W, and the substrate W is processed.

The processing liquid supply part 72 supplies processing liquid to the nozzle 71. The processing liquid supply part 72 includes one or a plurality of fluid-related equipment such as piping, joints, valves, pumps, tanks, and the like, and is connected to a processing liquid supply source (not shown). Here, as the processing liquid supply part 72, a valve 74 is disposed upstream of the nozzle 71. The valve 74 switches between a state where processing liquid is supplied to the nozzle 71 and a state where processing liquid is not supplied.

For the processing liquid, for example, pure water is used. For the processing liquid, a chemical liquid such as SC1 containing hydrogen peroxide water or ammonia water may be used.

The cup 60 is provided so as to surround a rotator (rotation drive part) 10 and a base part 20 described later in plan view. The cup 60 is provided so as to be movable in the up-down direction between an upper cup position and a lower cup position by the cup drive part 60X. The lower cup position is a height position (position in the up-down direction) where an upper end of the cup 60 is located below the substrate holding device SC. Moreover, the upper cup position is a height position where the upper end of the cup 60 is located above the substrate W held by the substrate holding device SC.

During processing of the substrate W, processing liquid is supplied from the nozzle 71 to the substrate W that is held and rotated by the substrate holding device SC. Therefore, the cup 60 is disposed at the upper cup position during processing of the substrate W. Thereby, the cup 60 catches the processing liquid scattered from the rotating substrate W. On the other hand, the cup 60 is disposed at the lower cup position while processing of the substrate W is not performed in the substrate processing device 1.

Moreover, during processing of the substrate W, in parallel with the supply of processing liquid from the nozzle 71 to the upper surface of the substrate W, the back rinse nozzle 65 supplies rinse liquid for back rinsing to a lower surface of the substrate W. The rinse liquid is, for example, pure water, but is not limited thereto. The back rinse supply part 66 supplies rinse liquid to the back rinse nozzle 65. The back rinse supply part 66 includes a valve and the like (not shown), and switches between a state where rinse liquid is supplied from a back rinse supply source (not shown) to the back rinse nozzle 65 and a state where rinse liquid is not supplied. By supplying rinse liquid to the lower surface of the substrate W, the lower surface of the substrate W is covered with rinse liquid. Thereby, the lower surface of the substrate W is protected by the rinse liquid. The cup 60 also catches the rinse liquid supplied from the back rinse nozzle 65 to the substrate W.

The cleaning brush 75 contacts an upper surface of the substrate W to perform scrub cleaning of the substrate W. The swing arm 76 holds the cleaning brush 75 at its tip. The swing arm 76 incorporates a brush drive part 76a that drives the cleaning brush 75 up and down and rotationally. For the brush drive part 76a, for example, a motor, an air cylinder and the like are used. The cleaning brush 75 is controlled by the brush drive part 76a to contact the substrate W with a predetermined pressing force or pressing amount while rotating.

The brush arm movement drive part 77 drives the swing arm 76. The brush arm movement drive part 77 includes a vertical drive part 77a that moves the swing arm 76 up and down along a vertical direction, and a horizontal drive part 77b that swings the swing arm 76 along a horizontal plane. With this configuration, the upper surface of the substrate W may be scrub cleaned by the cleaning brush 75 in the case of the substrate W being held by the substrate holding device SC.

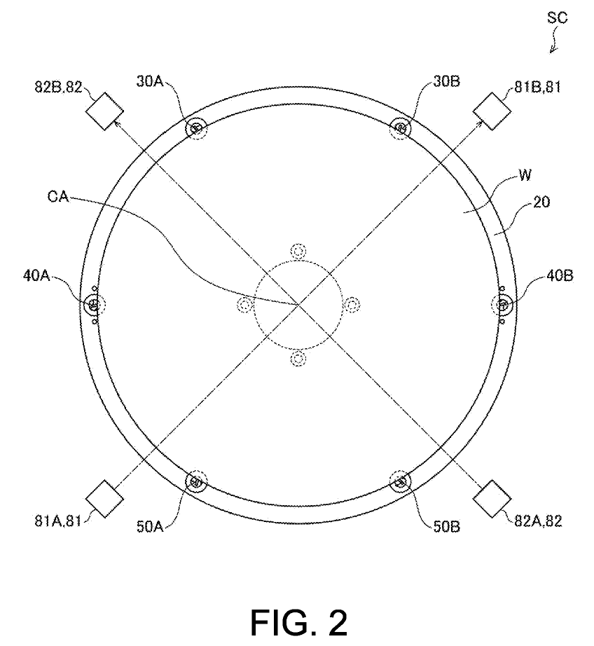

The substrate sensors 81 and 82 are configured to determine whether or not a part of the substrate W has ridden on any of a plurality of chuck pins (30A, 30B, 40A, 40B, 50A, 50B) described later in the case of the substrate W being placed on the substrate holding device SC. As shown in FIG. 1, the substrate sensors 81 and 82 are provided at an upper end of the substrate holding device SC, more specifically, at a height position slightly above upper ends of the plurality of chuck pins (30A, 30B, 40A, 40B, 50A, 50B). Moreover, the substrate sensors 81 and 82 respectively include light emitting parts 81A and 82A and light receiving parts 81B and 82B (FIG. 2).

The light emitting part 81A has a light emitting element. The light receiving part 81B has a light receiving element that receives light emitted from the light emitting part 81A. The light emitting part 81A and the light receiving part 81B constitute a transmission-type photoelectric sensor. The light emitting part 81A and the light receiving part 81B are arranged such that a straight line connecting the light emitting part 81A and the light receiving part 81B passes through a reference axis CA in plan view and crosses the substrate holding device SC and the cup 60.

The light emitting part 82A has a light emitting element. The light receiving part 82B has a light receiving element that receives light emitted from the light emitting part 82A. The light emitting part 82A and the light receiving part 82B constitute a transmission-type photoelectric sensor. The light emitting part 82A and the light receiving part 82B are arranged such that a straight line connecting the light emitting part 82A and the light receiving part 82B passes through the reference axis CA in plan view and crosses the substrate holding device SC and the cup 60, and is orthogonal to a straight line connecting the light emitting part 81A and the light receiving part 81B.

The controller 900 controls operations of each part of the substrate processing device 1 described above. Details of the controller 900 will be described later.

### Substrate Holding Device

FIG. 2 is a plan view showing an example of a configuration of the substrate holding device SC. As shown in FIG. 1 and FIG. 2, the substrate holding device SC includes a base part 20, a rotator 10, two fixed chuck pins 30A and 30B, two guide chuck pins 40A and 40B, two movable chuck pins 50A and 50B, and a chuck pin drive part 50X.

The base part 20 is provided rotatably around a reference axis CA extending in the up-down direction. The rotator 10 rotates the base part 20 around the reference axis CA. The rotator 10 is, for example, a motor and is fixed to a bottom part of the chamber. The rotator 10 has a rotating shaft 11 extending upward. A central axis of the rotating shaft 11 extends in the up-down direction. In the following description, the central axis of the rotating shaft 11 is referred to as the reference axis CA. The base part 20 is connected to an upper end of the rotating shaft 11. The base part 20 has a disk shape and is rotatably supported in a horizontal posture by the rotating shaft 11.

The two fixed chuck pins 30A and 30B and the two movable chuck pins 50A and 50B are members for holding the substrate W arranged on the base part 20. The two guide chuck pins 40A and 40B are members for supporting a lower surface of the substrate W arranged on the base part 20. In addition, the two guide chuck pins 40A and 40B are arranged at positions such that, in response to the substrate W being normally placed on the base part 20, they support the lower surface of the substrate W and are slightly separated from the side surface (outer peripheral end) of the substrate W. Accordingly, the guide chuck pins 40A and 40B regulate a horizontal position of the substrate W on the base part 20 during transport of the substrate W from outside the chamber to the substrate holding device SC. In addition, the guide chuck pins 40A and 40B assist in applying appropriate pressure to the substrate W by supporting the lower surface of the substrate W during scrub cleaning of the substrate W. These plurality of chuck pins (30A, 30B, 40A, 40B, 50A, 50B) are attached to the base part 20. Specifically, the plurality of chuck pins (30A, 30B, 40A, 40B, 50A, 50B) are attached to a peripheral part of the base part 20 at equal angular intervals (in this example, 60° intervals) with respect to the reference axis CA.

The plurality of chuck pins (30A, 30B, 40A, 40B, 50A, 50B) are arranged clockwise along a side surface (outer peripheral end) of the base part 20 in the order of the fixed chuck pin 30A, the fixed chuck pin 30B, the guide chuck pin 40B, the movable chuck pin 50B, the movable chuck pin 50A, and the guide chuck pin 40A in plan view. In this arrangement, the fixed chuck pin 30A and the movable chuck pin 50B face each other across the reference axis CA in plan view. In addition, the fixed chuck pin 30B and the movable chuck pin 50A face each other across the reference axis CA in plan view. Furthermore, the guide chuck pin 40A and the guide chuck pin 40B face each other across the reference axis CA in plan view.

The two fixed chuck pins 30A and 30B and the two guide chuck pins 40A and 40B are fixed to the base part 20 in a non-movable and non-rotatable manner. On the other hand, each of the two movable chuck pins 50A and 50B is attached to the base part 20 rotatably around a pin shaft PA. Each movable chuck pin 50A and 50B is switched between a holding state in which the movable chuck pin contacts a side surface (outer peripheral end) of the substrate W to hold the substrate by rotating relative to the base part 20, and a release state in which the movable chuck pin is separated from the side surface (outer peripheral end) of the substrate W. Details of the structure of each of the above chuck pins (30A, 30B, 40A, 40B, 50A, 50B) will be described later.

The number of the plurality of chuck pins (30A, 30B, 40A, 40B, 50A, 50B) may be any number capable of holding the substrate W, and is not limited to six described above. In addition, the number of chuck pins (movable chuck pins 50A and 50B) rotatably attached to the base part 20 is not limited to two. In addition, the guide chuck pins 40A and 40B may not need to be disposed on the base part 20. For example, two fixed chuck pins and one movable chuck pin may be attached to the peripheral part of the base part 20 at equal angular intervals (120° intervals) with respect to the reference axis CA.

The chuck pin drive part 50X may switch the rotatable movable chuck pins 50A and 50B between (i) a holding state in which the movable chuck pins contact an outer edge of the substrate W to hold the substrate W, and (ii) a release state in which the movable chuck pins may be separated from the outer edge of the substrate W, by rotating the movable chuck pins 50A and 50B around the pin shaft PA. The chuck pin drive part 50X includes, for example, a magnet and rotates the movable chuck pins 50A and 50B using magnetic force. The chuck pin drive part 50X is provided below the base part 20. The chuck pin drive part 50X is not limited to one using magnetic force, and may rotate the movable chuck pins 50A and 50B using a motor or air cylinder etc.

### Control System

The control system of the substrate processing device 1 will be described together with the configuration of the controller 900 in FIG. 3. FIG. 3 is a block diagram showing the configuration of the control system of the substrate processing device 1 in FIG. 1. As shown in FIG. 3, the controller 900 includes a CPU (Central Processing Unit) 910, a RAM (Random Access Memory) 920, a ROM (Read Only Memory) 930, and a memory device 940. The RAM 920 is used as a work area for the CPU 910. The ROM 930 stores a system program. The memory device 940 includes a storage medium such as a hard disk or semiconductor memory, and stores a substrate processing program. The substrate processing program in this example is a program for supplying processing liquid to the substrate W.

Here, the substrate processing program in FIG. 3 may be provided in a state stored in a recording medium such as a CD-ROM 990, and installed in the ROM 930 or the memory device 940. Alternatively, the substrate processing program may be distributed from a server external to the substrate processing device 1 via a communication network, and installed in the ROM 930 or the memory device 940. The operation of each part of the substrate processing device 1 is controlled by the CPU 910 executing the substrate processing program.

The rotator 10 is provided with a rotary encoder 12 that detects a rotation amount of a rotor (not shown) of the rotator 10 and outputs a signal indicating the rotation amount. The controller 900 controls the rotator 10 based on the signal output from the rotary encoder 12. Thereby, the substrate holding device SC rotates at a predetermined speed. Also, the rotation position (rotation angle) of the substrate holding device SC is adjusted.

The controller 900 controls the nozzle moving device 73. The controller 900 moves the nozzle 71 between a processing position above the substrate holding device SC and a standby position lateral to the substrate holding device SC by controlling the nozzle moving device 73.

The controller 900 controls the brush drive part 76a. By the brush drive part 76a being controlled by the controller 900, the cleaning brush 75 contacts the substrate W with a predetermined pressing force or pressing amount while rotating.

The controller 900 controls the processing liquid supply part 72. Specifically, the controller 900 controls the valve 74 of the processing liquid supply part 72, and controls the supply of processing liquid from the nozzle 71 to the upper surface of the substrate W.

The controller 900 controls the back rinse supply part 66. Specifically, by controlling a valve (not shown) of the back rinse supply part 66, the controller controls the supply of rinse liquid from the back rinse nozzle 65 to the lower surface of the substrate W.

Also, the controller 900 controls the chuck pin drive part 50X. Thereby, the state of the movable chuck pins 50A and 50B of the substrate holding device SC is switched between the holding state and the release state.

Also, the controller 900 controls the cup drive part 60X. Thereby, the cup 60 of FIG. 1 moves between an upper cup position and a lower cup position according to the timing of transfer of the substrate W to and from the substrate holding device SC and the timing at which processing liquid is supplied to the substrate W.

Also, the controller 900 controls the substrate sensors 81 and 82. Specifically, the controller 900 controls the light emitting part 81A of the substrate sensor 81, thereby causing light to be emitted from the light emitting part 81A to the light receiving part 81B. Also, the controller 900 controls the light emitting part 82A of the substrate sensor 82, thereby causing light to be emitted from the light emitting part 82A to the light receiving part 82B.

In the case of control of the substrate sensors 81 and 82 by the controller 900, a light receiving signal indicating the amount of received light of the light receiving part is output from each light receiving element of the light receiving parts 81B and 82B. The light receiving signal is provided to the controller 900. In this case, the controller 900 determines whether or not a part of the substrate W has ridden up on any of the plurality of chuck pins (30A, 30B, 40A, 40B, 50A, 50B) based on the light receiving signals provided from the substrate sensors 81 and 82 (light receiving parts 81B and 82B).

For example, in the case of a part of the substrate W riding up on any of the plurality of chuck pins (30A, 30B, 40A, 40B, 50A, 50B), that part of the substrate W is positioned above the substrate holding device SC. Thereby, the light path between the light emitting part 81A and the light receiving part 81B is blocked. Alternatively, the light path between the light emitting part 82A and the light receiving part 82B is blocked. Therefore, the controller 900 determines that a part of the substrate W is riding up on a chuck pin in the case of the light receiving signal output from either of the light receiving parts 81B and 82B indicating an amount of received light of "0". On the other hand, the controller 900 determines that the substrate W is appropriately placed on the substrate holding device SC in the case of the light receiving signals output from the light receiving parts 81B and 82B indicating an amount of received light greater than "0".

As shown in FIG. 3, the substrate processing device 1 further includes an alarm device 91 and an operation part 92. The alarm device 91 is an output device that outputs an alarm. The alarm device 91 may include a display device that displays an image of abnormality occurrence, may include a warning light that notifies of abnormality occurrence, or may include an audio output device that outputs audio of abnormality occurrence. The controller 900 controls the alarm device 91 to output an alarm, for example, in the case of determining that the substrate W is riding up on the substrate holding device SC based on the detection results of the substrate sensors 81 and 82. On the other hand, the controller 900 maintains the alarm device 91 in a stopped state in the case of determining that the substrate W is appropriately placed on the substrate holding device SC.

The operation part 92 includes a keyboard and a pointing device, and is configured to be operable by a user. The user may set various operating conditions of the substrate processing device 1 by operating the operation part 92.

### Chuck Pin

The fixed chuck pins 30A and 30B and the guide chuck pins 40A and 40B have the same configuration as each other. Representing these chuck pins (30A, 30B, 40A, 40B), the details of the fixed chuck pin 30B will be described.

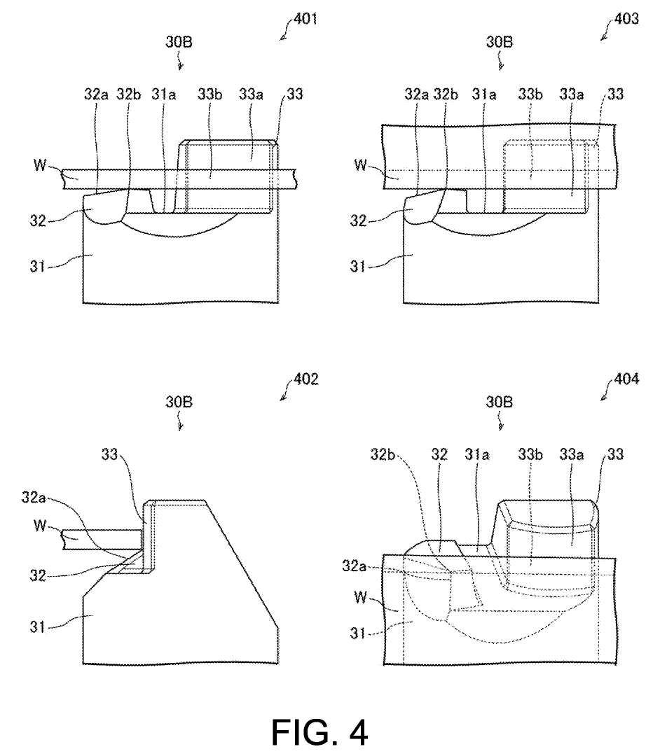

FIG. 4 is a diagram showing an example of the configuration of the fixed chuck pin 30B. In FIG. 4, reference numeral 401 is a side view of the fixed chuck pin 30B. Reference numeral 402 is a side view of the fixed chuck pin 30B different from reference numeral 401. Reference numeral 403 is a perspective view of the fixed chuck pin 30B viewed obliquely from below. Reference numeral 404 is a perspective view of the fixed chuck pin 30B viewed obliquely from above. As shown in FIG. 4, the fixed chuck pin 30B includes a main body part 31, a lower surface support part 32, and a side surface grip part 33. In the fixed chuck pin 30B, the main body part 31, the lower surface support part 32, and the side surface grip part 33 are integrally formed.

The main body part 31 supports the lower surface support part 32 and the side surface grip part 33. The main body part 31 has a main surface 31a at an upper portion. The main surface 31a is a surface parallel to a horizontal plane in the case of the main body part 31 being disposed on the base part 20. The main surface 31a is a surface parallel to the lower surface of the substrate W in the case of holding the substrate W. Also, the main surface 31a does not contact the lower surface and side surface (outer peripheral end) of the substrate W.

The lower surface support part 32 supports the lower surface of the substrate W. The lower surface support part 32 is provided to protrude upward from the main surface 31a. In other words, the lower surface support part 32 supports the lower surface of the substrate W at a position higher than the main surface 31a of the main body part 31. The lower surface support part 32 is formed at one end of the main surface 31a. The lower surface support part 32 contacts only the lower surface of the substrate W and does not contact the side surface (outer peripheral end) of the substrate W. Moreover, the lower surface support part 32 may contact the chamfered portion on the lower surface side of the substrate W.

The side surface grip part 33 grips the side surface of the substrate W. The side surface grip part 33 is provided to protrude upward from the main surface 31a while being separated from the lower surface support part 32. Also, the side surface grip part 33 protrudes upward more than the lower surface support part 32. In other words, the side surface grip part 33 contacts the side surface of the substrate W at a position higher than the main surface 31a of the main body part 31 and grips the substrate W. Also, the side surface grip part 33 grips the substrate W by contacting the side surface of the substrate W at a position higher than the contact position of the lower surface of the substrate W of the lower surface support part 32. The side surface grip part 33 is formed at the other end of the main surface 31a. The side surface grip part 33 does not overlap with the lower surface support part 32 in plan view. The side surface grip part 33 does not contact the lower surface of the substrate W and contacts only the side surface (outer peripheral end) of the substrate W.

Moreover, the movable chuck pins 50A and 50B have the same configuration as each other. Next, the details of the movable chuck pin 50B will be described as a representative of the movable chuck pins 50A and 50B.

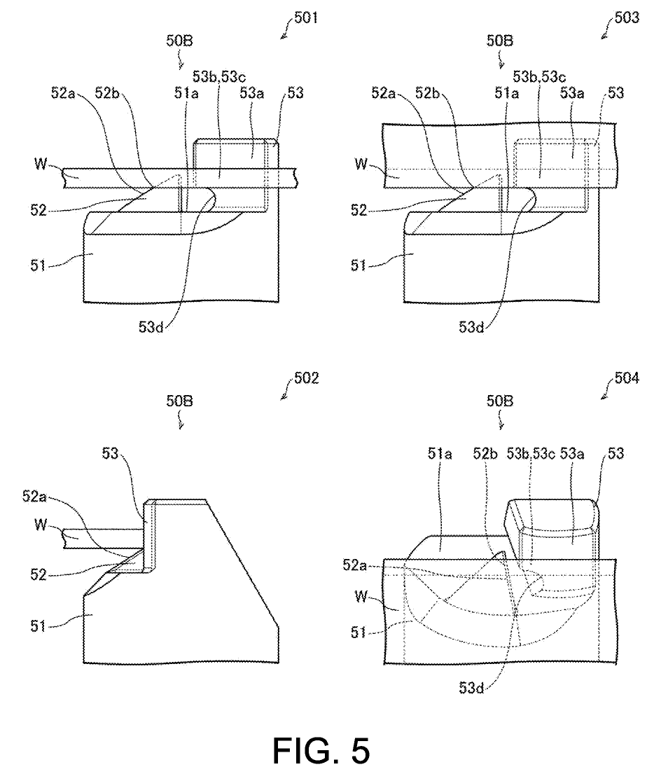

FIG. 5 is a diagram showing an example of the configuration of the movable chuck pin 50B. In FIG. 5, reference numeral 501 is a side view of the movable chuck pin 50B. Reference numeral 502 is a side view of the movable chuck pin 50B different from reference numeral 501. Reference numeral 503 is a perspective view of the movable chuck pin 50B viewed obliquely from below. Reference numeral 504 is a perspective view of the movable chuck pin 50B viewed obliquely from above. As shown in FIG. 5, the movable chuck pin 50B includes a main body part 51, a lower surface support part 52, and a side surface grip part 53. In the movable chuck pin 50B, the main body part 51, the lower surface support part 52, and the side surface grip part 53 are integrally formed.

The main body part 51 supports the lower surface support part 52 and the side surface grip part 53. The main body part 51 has a main surface 51a at an upper portion. The main surface 51a is a surface parallel to a horizontal plane in the case of the main body part 51 being disposed on the base part 20. The main surface 51a is a surface parallel to the lower surface of the substrate W in the case of holding the substrate W. Also, the main surface 51adoes not contact the lower surface and side surface (outer peripheral end) of the substrate W.

The lower surface support part 52 supports the lower surface of the substrate W. The lower surface support part 52 is provided to protrude upward from the main surface 51a. In other words, the lower surface support part 52 supports the lower surface of the substrate W at a position higher than the main surface 51a of the main body part 51. The lower surface support part 52 is formed at one end of the main surface 51a. The lower surface support part 52 contacts only the lower surface of the substrate W and does not contact the side surface (outer peripheral end) of the substrate W. Moreover, the lower surface support part 52 may contact the chamfered portion on the lower surface side of the substrate W.

The side surface grip part 53 grips the side surface of the substrate W. The side surface grip part 53 is provided to protrude upward from the main surface 51a while being separated from the lower surface support part 52. Also, the side surface grip part 53 protrudes upward more than the lower surface support part 52. In other words, the side surface grip part 53 contacts the side surface of the substrate W at a position higher than the main surface 51a of the main body part 51 and grips the substrate W. Also, the side surface grip part 53 contacts the side surface of the substrate W at a position higher than the contact position of the lower surface support part 52 with the lower surface of the substrate W and grips the substrate W. The side surface grip part 53 is formed at the other end of the main surface 51a. The side surface grip part 53 does not overlap with the lower surface support part 52 in plan view. The side surface grip part 53 does not contact the lower surface of the substrate W and contacts only the side surface (outer peripheral end) of the substrate W.

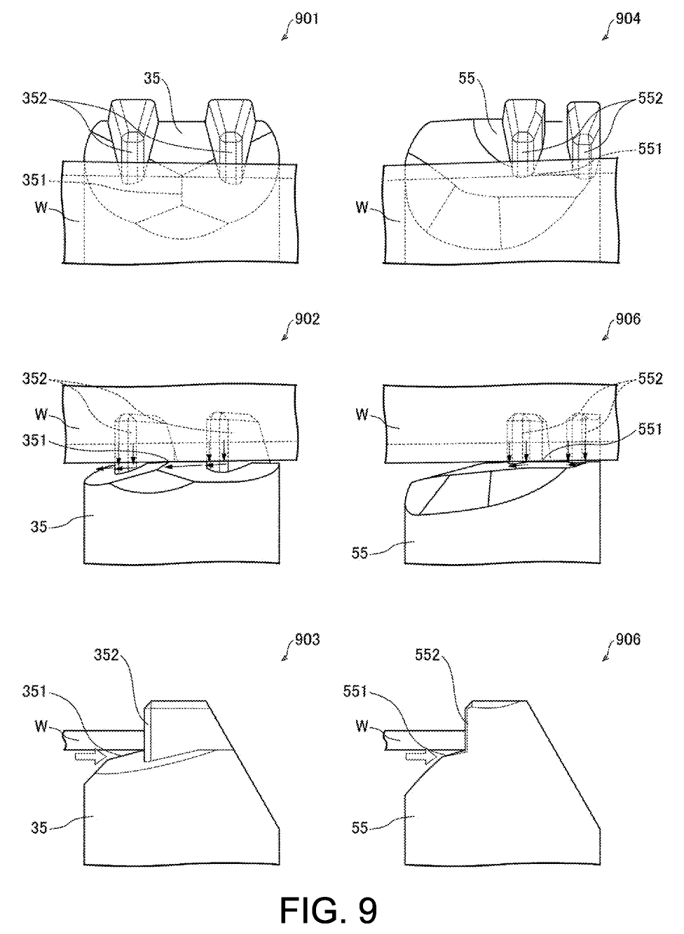

Here, with reference to the Comparative Example of FIG. 9, problems that occur in the substrate W in the case of a configuration in which the side surface grip part and the lower surface support part are provided in contact with each other will be described. Although details will be described later, in the substrate processing device of the Comparative Example shown in FIG. 9, in the case of a part of the processing liquid supplied to the upper surface of the substrate W contacting side surface grip parts 352 and 552, the processing liquid moves downward by capillary phenomenon in the space between the substrate W and the side surface grip parts 352 and 552. Also, in response to such processing liquid traveling along the side surface grip parts 352 and 552 and reaching between lower surface support parts 351 and 551 and the substrate W, a situation where the processing liquid moves in the center direction through a narrow gap between the lower surface support parts 351 and 551 and the lower surface of the substrate W by capillary phenomenon is likely to occur. Also, in the substrate processing device of the Comparative Example shown in FIG. 9, because the space between the lower surface support parts 351 and 551 and the lower surface of the substrate W is narrow, a situation where a part of the processing liquid supplied to the lower side surface of the substrate W also remains in that narrow space occurs.

In contrast, in the substrate processing device 1 according to the present embodiment, the side surface grip parts 33 and 53 are provided separated from the lower surface support parts 32 and 52. Therefore, the processing liquid is unlikely to move from the side surface grip parts 33 and 53 along the lower surface support parts 32 and 52 to the lower side surface of the substrate W. For example, the lower surface support parts 32 and 52 may be formed at a height separated by 1 mm to 3 mm from the main surfaces 31a and 51a of the main body parts 31 and 51. The height of the lower surface support parts 32 and 52 may be appropriately designed according to the surface tension of the processing liquid, the contact angle between the processing liquid and the main surfaces 31a and 51a of the main body parts 31 and 51, and/or the density of the processing liquid.

In the case of the substrate W being held in the substrate holding device SC with the device surface on which circuits and other devices are formed as the lower side surface, the processing liquid remaining on the lower side surface of the substrate W may cause adverse effects such as collapse of circuit patterns or generation of particles derived from the processing liquid. Each of the chuck pins (30A, 30B, 40A, 40B, 50A, 50B) described above has the above configuration, thereby making it difficult for the processing liquid to remain on the surface of the substrate W. Also, the substrate holding device SC including each chuck pin (30A, 30B, 40A, 40B, 50A, 50B), and furthermore the substrate processing device 1 including the substrate holding device SC, achieve similar effects.

Specifically, the main body part 31 further includes a groove part 31b provided between the lower surface support part 32 and the side surface grip part 33. Also, the main body part 51 further includes a groove part 51b provided between the lower surface support part 52 and the side surface grip part 53. The groove parts 31b and 51b are formed to be open radially outward as viewed from the reference axis CA in the main body parts 31 and 51. In other words, the radially outer opening of the groove parts 31b and 51b is larger than the radially inner opening. This allows the processing liquid to be discharged radially as viewed from the reference axis CA through the groove parts 31b and 51b. Also, the groove parts 31b and 51b are formed by mutually opposing side surfaces of the lower surface support part 32 and the side surface grip part 33, and the main surface 31a of the main body part. In other words, the lower surfaces of the groove parts 31b and 51b are at the same height as the main surfaces 31a and 51a of the main body part. This allows the processing liquid to be suitably discharged radially outward without anything blocking the processing liquid.

The side surface grip part 53 has a grip part 53c that is a portion including a surface that contacts the substrate W when gripping the substrate W, and a non-grip part 53d that is a portion provided below the grip part 53c without contacting the substrate W when gripping the substrate W. That is, the grip part 53c and the non-grip part 53d have a structure stacked up and down. In the movable chuck pin 50B, the groove part 51b is formed below the grip part 53c. Furthermore, the groove part 51b at least partially overlaps with the grip part 53c in plan view. In other words, at least a part of the surface of the non-grip part 53d on the groove part 51b side is positioned more inward in the side surface grip part 53 than the surface of the grip part 53c on the groove part 51b side.

The lower surface support part 52 of the movable chuck pin 50B needs to support the lower surface of the substrate W in both the release state and the holding state. For this reason, the lower surface support part 52 is formed larger compared to the lower surface support part 32. In other words, the region between the lower surface support part 52 and the side surface grip part 53 in plan view becomes narrower compared to the region between the lower surface support part 32 and the side surface grip part 33.

In contrast, as described above, the movable chuck pin 50B has a configuration in which at least a part of the groove part 51b overlaps with the side surface grip part 53 in plan view, thereby enabling the volume of the groove part 51b to be formed larger compared to a case without such configuration. Therefore, the possibility that the liquid level of the processing liquid flowing through the groove part 51b rises and contacts the lower surface of the substrate W is reduced. Moreover, the groove parts 31b in the fixed chuck pins 30A and 30B and the guide chuck pins 40A and 40B may similarly have at least a part overlapping with a grip part 33c in plan view.

Also, the lower surface support part 32 has a ridge part 32a for supporting the substrate W. The lower surface support part 52 has a ridge part 52a for supporting the substrate W. The side surface grip part 33 has a grip surface 33a for gripping the substrate W. The side surface grip part 53 has a grip surface 53a for gripping the substrate W.

The lower surface support parts 32 and 52 support the substrate W at one point of the ridge parts 32a and 52a. Furthermore, the side surface grip parts 33 and 53 support the end surface (side surface) of the substrate W at one point of the grip surfaces 33a and 53a. For this reason, the contact area of the lower surface support parts 32 and 52 and the side surface grip parts 33 and 53 with the substrate W is minimized. Thereby, even in the case where processing liquid remains at the contact points of the lower surface support parts 32 and 52 and the side surface grip parts 33 and 53 with the substrate W, the amount thereof may be minimized.

Moreover, the lower surface support parts 32 and 52 may each have a support surface that is a surface for supporting the substrate W instead of the ridge parts 32a and 52a, and may support the substrate W at one point of the support surface. Also, the side surface grip parts 33 and 53 may each support the end surface (side surface) of the substrate W in a linear region rather than at one point within the grip surfaces 33a and 53a.

The angle of the ridge parts 32a and 52a or the support surfaces in the lower surface support parts 32 and 52 with respect to the horizontal plane is 26 degrees to 33 degrees. In the case where the angle is less than 26 degrees, particles are likely to be generated on the lower surface of the substrate W. Also, in the case where the angle is greater than 33 degrees, the lower surface support parts 32 and 52 are likely to deteriorate with use.

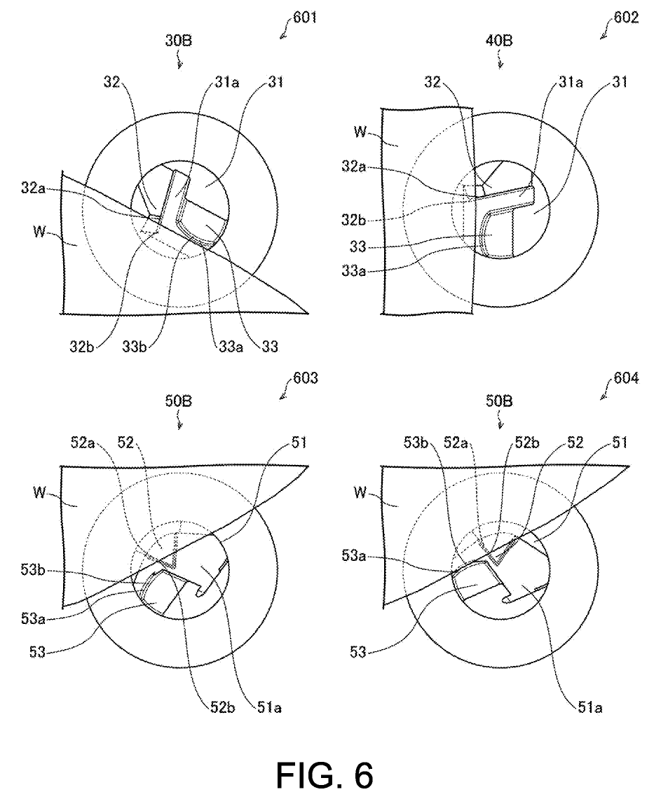

FIG. 6 is a diagram for describing the fixed chuck pin 30B, the guide chuck pin 40B, and the movable chuck pin 50B in the case where the substrate holding device SC grips the substrate W. In FIG. 6, reference numeral 601 is a plan view showing the fixed chuck pin 30B. Reference numeral 602 is a plan view showing the guide chuck pin 40B. Reference numeral 603 is a plan view showing the movable chuck pin 50B in the release state. Reference numeral 604 is a plan view showing the movable chuck pin 50B in the holding state. In reference numeral 602, the guide chuck pin 40B is configured to include a main body part 31, a lower surface support part 32, and a side surface grip part 33, similar to the fixed chuck pin 30B.

As shown by reference numeral 601, the substrate W is placed on the substrate holding device SC so as to contact the side surface grip part 33 of the fixed chuck pin 30B. As shown by reference numeral 602, the substrate W is placed on the substrate holding device SC so as to be separated from the side surface grip part 33 of the guide chuck pin 40B by a minute distance. The minute distance may be, for example, 0.5 mm, but is not limited thereto. The positional relationship between the substrate W and the fixed chuck pin 30B and the guide chuck pin 40B does not change before and after the substrate holding device SC grips the substrate W.

As shown by reference numeral 603, the substrate W is placed on the substrate holding device SC so as to be separated from the side surface grip part 53 of the movable chuck pin 50B in the release state. In that state, the movable chuck pin 50B rotates, and as shown by reference numeral 604, the substrate W is gripped by the movable chuck pin 50B in which the side surface grip part 53 contacts the substrate W and becomes in the holding state.

In FIG. 6, support positions 32b and 52b are positions where the substrate W is supported in the lower surface support parts 32 and 52. The support positions 32b and 52b are each one point of the above-described ridge parts 32a and 52a. Grip positions 33b and 53b are positions where the substrate W is gripped in the side surface grip parts 33 and 53. The grip positions 33b and 53b are each one point of the above-described grip surfaces 33a and 53a.

The support position 32b and the grip position 33b are in mutually different directions in plan view as viewed from the reference axis CA. Also, the support position 52b and the grip position 53b are in mutually different directions in plan view as viewed from the reference axis CA. Accordingly, the distance between the support positions 32b and 52b and the grip positions 33b and 53b may be made large, and the positions where the grip positions 33b and 53b contact the substrate W may be made near the outer edge of the substrate W.

The reference axis CA does not appear in FIG. 6. However, the substrate W is circular, and the center of the substrate W substantially coincides with the reference axis CA in plan view. Therefore, it is clear that the support positions 32b and 52b and the grip positions 33b and 53b are in mutually different directions in plan view as viewed from the reference axis CA grasped from the contour of the substrate W in FIG. 6.

In particular, the lower surface support parts 32 and 52 support a region in the range of 0.1 mm to 0.6 mm from the end surface (side surface) of the substrate W on the lower surface of the substrate W. Generally, devices are not formed in such a region even on the device surface. Therefore, the lower surface support parts 32 and 52 may support the substrate W without contacting the devices even in the case of supporting the substrate W with the device surface as the lower surface.

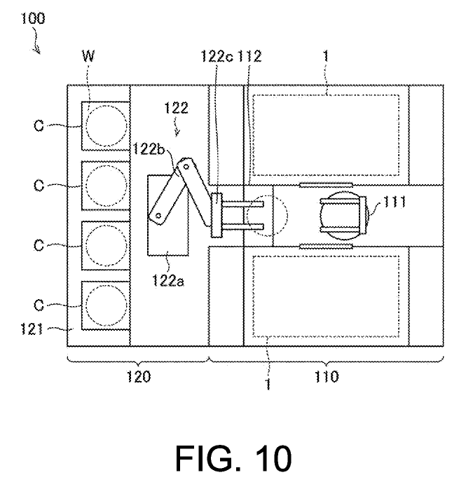

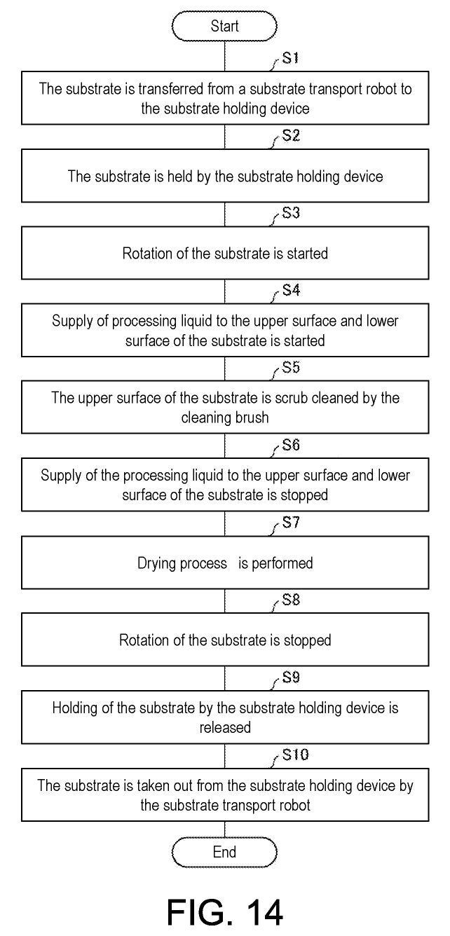

FIG. 14 is a flowchart showing one example of a substrate processing method by a substrate processing system 100 equipped with the substrate processing device 1. The substrate processing system 100 and its components will be described later with reference to FIG. 10.

In the example shown in FIG. 14, first, the substrate W is transferred from a substrate transport robot 111 to the substrate holding device SC (S1). Next, the substrate W is held by the substrate holding device SC (S2). In that state, rotation of the substrate W is started by rotating the base part 20 with the rotator 10 (S3).

Supply of processing liquid from the nozzle 71 and the back rinse nozzle 65 to the upper surface and lower surface of the rotating substrate W is started (S4). In that state, the upper surface of the substrate W is scrub cleaned by the cleaning brush 75 (S5). After completion of the scrub cleaning, supply of the processing liquid to the upper surface and lower surface of the substrate W is stopped (S6). Furthermore, drying process of the substrate W is performed by increasing the rotation speed of the base part 20 by the rotator 10 (S7).

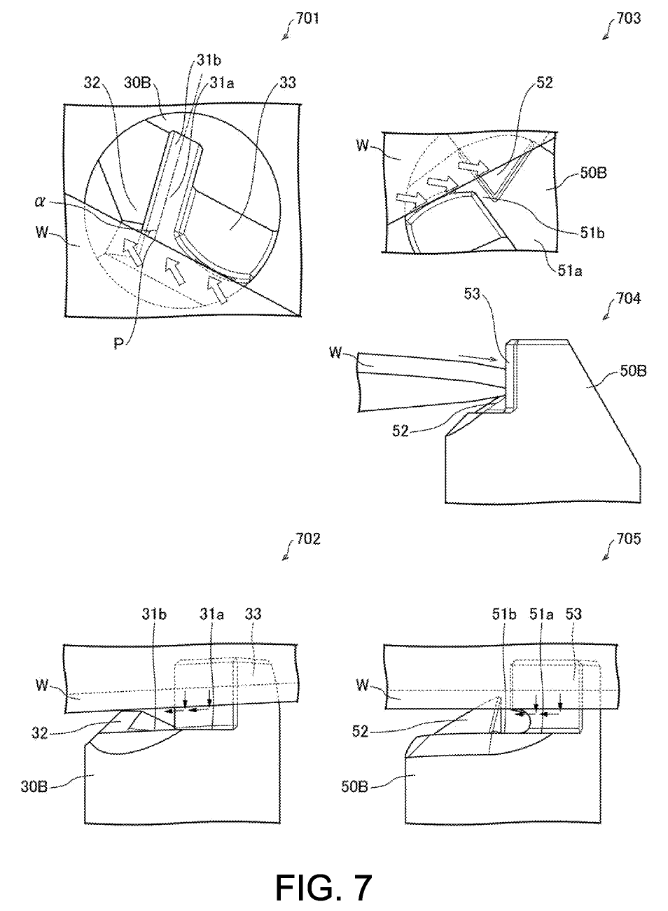

FIG. 7 is a diagram showing the flow of processing liquid on the upper surface side of the substrate W. In FIG. 7, reference numeral 701 is a plan view of the vicinity of the fixed chuck pin 30B as viewed from above. Reference numeral 702 is a perspective view of the vicinity of the fixed chuck pin 30B as viewed obliquely from below. Reference numeral 703 is a plan view of the vicinity of the movable chuck pin 50B as viewed from above. Reference numeral 704 is a perspective view of the vicinity of the movable chuck pin 50B as viewed obliquely from below. Reference numeral 705 is a perspective view of the vicinity of the movable chuck pin 50B as viewed obliquely from below in a different direction from reference numeral 704.

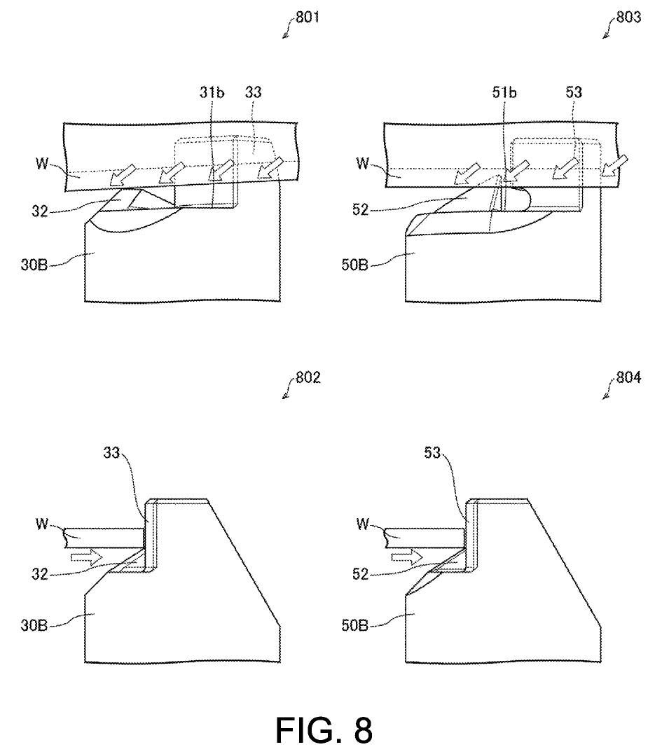

FIG. 8 is a diagram showing the flow of processing liquid on the lower surface side of the substrate W. In FIG. 8, reference numeral 801 is a plan view of the vicinity of the fixed chuck pin 30B as viewed from above. Reference numeral 802 is a side view of the vicinity of the fixed chuck pin 30B. Reference numeral 803 is a plan view of the vicinity of the movable chuck pin 50B as viewed from above. Reference numeral 804 is a side view of the vicinity of the movable chuck pin 50B.

In the scrub process and drying process, as shown in FIG. 7 and FIG. 8, on both the upper surface side and lower surface side of the substrate W, the processing liquid moves to the outer edge of the substrate W as indicated by the white arrows due to centrifugal force generated by rotation of the substrate W. Moreover, in the chuck pins of the present embodiment, the only components that protrude above the upper surface of the substrate W are the side surface grip parts 33 and 53. Therefore, this may prevent the processing liquid flowing around from the upper surface to the lower surface of the substrate W.

Moreover, the processing liquid on the upper surface side of the substrate W flows along the side surface grip parts 33 and 53 to the groove parts 31b and 51b as indicated by the black arrows, and flows outward within the groove parts 31b and 51b in a direction away from the reference axis CA. At this time, since a gap wider than the Comparative Example shown in FIG. 9 described later exists between the groove parts 31b and 51b and the substrate W, the processing liquid easily flows outward. Moreover, the space between the lower surface support parts 32 and 52 and the lower surface of the substrate W is wider than the Comparative Example shown in FIG. 9 described later, and movement of processing liquid due to capillary phenomenon does not occur. In other words, since the only components that approach the lower surface of the substrate W are the lower surface support parts 32 and 52, the area of the chuck pins that approach the lower surface of the substrate W is minimized, and movement of processing liquid due to capillary phenomenon can be reduced. Therefore, the processing liquid flowing through the groove parts 31b and 51b becomes less likely to adhere to the lower surface of the substrate W.

Moreover, the processing liquid on the lower surface side of the substrate W also moves to the outer edge of the substrate W through the wide space between the lower surface support parts 32 and 52 and the lower surface of the substrate W due to centrifugal force generated by rotation of the substrate W.

Moreover, in reference numeral 701 of FIG. 7, a point P is a point between the lower surface support parts 32 and 52 and the side surface grip parts 33 and 53. An angle α is the angle in the outward direction in which the groove parts 31b and 51b are open when viewed from the point P in plan view, with respect to the tangential direction of the disk-shaped substrate W in the direction opposite to the rotation direction of the base part 20. The angle α is preferably in an angular range of 12 degrees or more and less than 90 degrees. This angular range is the angular range in which processing liquid is discharged by centrifugal force generated by rotation of the substrate W. Therefore, by having the groove parts 31b and 51b open in this direction, processing liquid may be discharged promptly.

FIG. 9 is a diagram showing the flow of processing liquid in one example of a substrate holding device of a Comparative Example. The substrate holding device of the Comparative Example illustrated in FIG. 9 includes a fixed chuck pin 35 instead of the fixed chuck pin 30B, and includes a movable chuck pin 55 instead of the movable chuck pin 50B. In FIG. 9, reference numeral 901 is a perspective view of the vicinity of the fixed chuck pin 35 as viewed obliquely from above. Reference numeral 902 is a perspective view of the vicinity of the fixed chuck pin 35 as viewed obliquely from below. Reference numeral 903 is a side view of the vicinity of the fixed chuck pin 35. Reference numeral 904 is a perspective view of the vicinity of the movable chuck pin 55 as viewed obliquely from above. Reference numeral 905 is a perspective view of the vicinity of the movable chuck pin 55 as viewed obliquely from below. Reference numeral 906 is a side view of the vicinity of the movable chuck pin 55. Moreover, in reference numerals 903 and 904, the flow of processing liquid is indicated by arrows.

The fixed chuck pin 35 has a lower surface support part 351 and a side surface grip part 352. The lower surface support part 351 supports the lower surface of the substrate W. The lower surface support part 351 contacts only the lower surface of the substrate W and does not contact the side surface (outer peripheral end) of the substrate W. The side surface grip part 352 grips the side surface of the substrate W. The side surface grip part 352 does not contact the lower surface of the substrate W and contacts only the side surface (outer peripheral end) of the substrate W. The lower surface support part 351 and the side surface grip part 352 are continuous with each other.

The movable chuck pin 55 has a lower surface support part 551 and a side surface grip part 552. The lower surface support part 551 supports the lower surface of the substrate W. The lower surface support part 551 contacts only the lower surface of the substrate W and does not contact the side surface (outer peripheral end) of the substrate W. The side surface grip part 552 grips the side surface of the substrate W. The side surface grip part 552 does not contact the lower surface of the substrate W and contacts only the side surface (outer peripheral end) of the substrate W. The lower surface support part 551 and the side surface grip part 552 are continuous with each other.

In the scrub process and drying process in the substrate holding device of the Comparative Example, similarly to the substrate holding device SC, the processing liquid moves to the outer edge of the substrate W by centrifugal force generated by rotation of the substrate W. Here, in the fixed chuck pin 35, as indicated by black arrows in reference numeral 902, the processing liquid supplied to the upper surface of the substrate W flows around from the outer edge of the substrate W along the side surface grip part 352 to the lower surface of the substrate W. Furthermore, the processing liquid moves to the lower surface support part 351 that is continuous with the side surface grip part 352, and moves in the center direction through a narrow gap between the lower surface support part 351 and the substrate W by capillary phenomenon. Also in the movable chuck pin 55, as indicated by black arrows in reference numeral 905, the processing liquid supplied to the upper surface of the substrate W flows around from the outer edge of the substrate W along the side surface grip part 552 to the lower surface of the substrate W. Furthermore, the processing liquid moves to the lower surface support part 551 that is continuous with the side surface grip part 552, and moves in the center direction through a narrow gap between the lower surface support part 551 and the substrate W by capillary phenomenon.

Also, in the substrate holding device of the Comparative Example, the space between the substrate W and the fixed chuck pin 35 and the movable chuck pin 55 is narrower compared to the substrate processing device 1. Therefore, the processing liquid that is supplied to the lower surface of the substrate W and moves to the outer edge of the substrate W by centrifugal force generated by rotation of the substrate W also moves again in the center direction through the space between the lower surface support parts 351 and 551 and the substrate W by capillary phenomenon.

Also, the processing liquid on the lower surface of the substrate W moves to the outer edge of the substrate W by centrifugal force generated by rotation of the substrate W, as indicated by white arrows in reference numerals 903 and 906. However, because the space between the lower surface support parts 351 and 551 and the lower surface of the substrate W is narrow, a situation occurs in which part of the processing liquid supplied to the lower side surface of the substrate W remains in that narrow space.

Returning to FIG. 14, after completion of the drying process, rotation of the substrate W is stopped (S8), and holding of the substrate W by the substrate holding device SC is released (S9). Thereafter, the substrate W is taken out from the substrate holding device SC by the substrate transport robot 111 (S10).

### Substrate Processing System

FIG. 10 is a plan view showing a schematic configuration of a substrate processing system 100 equipped with the substrate processing device 1. This does not show the appearance of the substrate processing system 100, but is a schematic diagram that clearly shows the internal structure by excluding the outer wall panels and some other components of the substrate processing system 100. This substrate processing system 100 is, for example, a single-wafer type device that is installed in a clean room and processes substrates W (workpieces) one by one. The main configuration of the substrate processing system 100 shown here is similar to that described in Japanese Patent Application No. 2022-134816 filed by the applicant of the present application.

The substrate processing system 100 includes a plurality of substrate processing devices 1, each functioning as a processing unit that mainly performs processing on the substrate W. The plurality of substrate processing devices 1 are stacked in a plurality of stages in the up-down direction. For example, the substrate processing devices 1 may be arranged in a stacked manner over 4 stages. In FIG. 10, the substrate processing devices 1 arranged in a stacked manner as described above are disposed on both sides of a passage through which the substrate transport robot 111 described later moves. Therefore, the substrate processing system 100 includes a total of 8 substrate processing devices 1.

As shown in FIG. 10, the substrate processing system 100 has a substrate processing area 110 that performs processing on the substrate W. An indexer part 120 is provided adjacent to this substrate processing area 110. The indexer part 120 has a container holder (container holding part) 121 that may hold a plurality of containers C (FOUP (Front Opening Unified Pod), SMIF (Standard Mechanical Interface) pod, OC (Open Cassette) and the like that accommodate a plurality of substrates W in a sealed state) for accommodating the substrate W. Also, the indexer part 120 includes an indexer robot 122 for accessing the container C held by the container holder 121 to take out unprocessed substrates W from the container C and to store processed substrates W in the container C. In each container C, a plurality of substrates W are accommodated in a substantially horizontal posture.

The indexer robot 122 includes a main body part 122a fixed to the device housing, a joint arm 122b provided to be rotatable around a vertical axis with respect to the main body part 122a, and a hand 122c attached to the tip of the joint arm 122b. The hand 122c has a structure that may place and hold the substrate W on its upper surface. Since an indexer robot having such a joint arm and a hand for holding substrates is known, detailed description thereof is omitted.

In the substrate processing area 110, a placement stage 112 is provided such that the substrate W from the indexer robot 122 may be placed thereon. Also, in plan view, a substrate transport robot 111 is disposed substantially at the center of the substrate processing area 110. Furthermore, a plurality of substrate processing devices 1 are disposed so as to surround this substrate transport robot 111. Specifically, the plurality of substrate processing devices 1 are disposed facing the space where the substrate transport robot 111 is disposed. The substrate transport robot 111 randomly accesses the placement stage 112 with respect to these substrate processing devices 1, and transfers the substrate W to and from the placement stage 112. On the other hand, each substrate processing device 1 executes predetermined processing on the substrate W. In the present embodiment, these substrate processing devices 1 have the same function. Therefore, parallel processing of a plurality of substrates W is enabled. Moreover, the placement stage 112 is not necessarily required if the substrate transport robot 111 may directly transfer the substrate W from the indexer robot 122.

### Embodiment 2

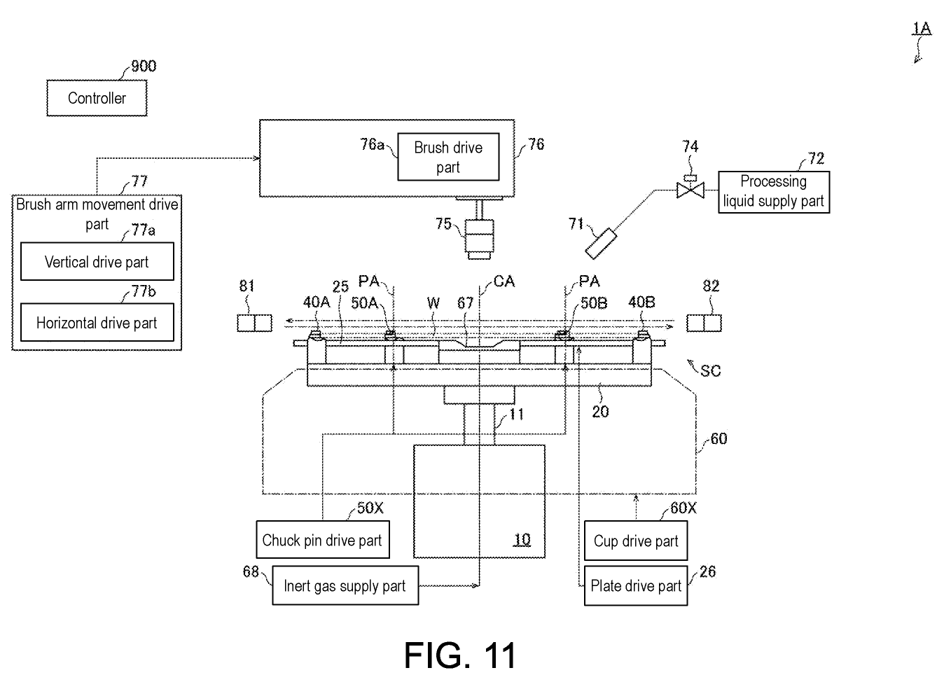

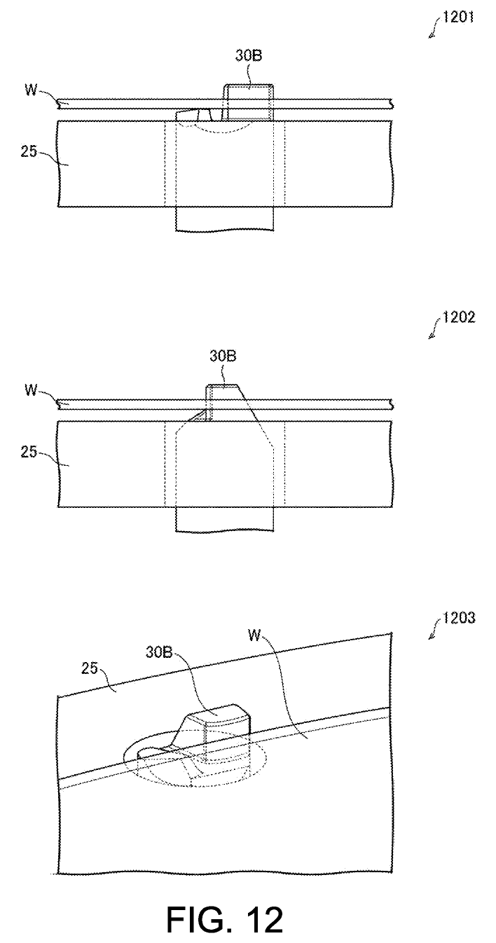

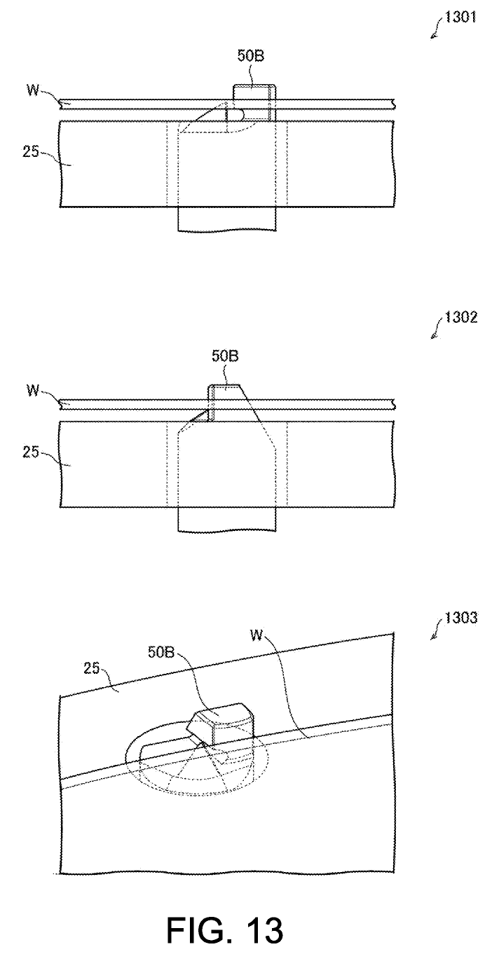

FIG. 11 is a schematic side view showing the configuration of a substrate processing device 1A according to Embodiment 2. FIG. 12 is a diagram showing the vicinity of a fixed chuck pin 30B in the substrate holding device SC of the substrate processing device 1A. In FIG. 12, reference numeral 1201 is a side view of the vicinity of the fixed chuck pin 30B. Reference numeral 1202 is a side view of the vicinity of the fixed chuck pin 30B, which is different from reference numeral 1201. Reference numeral 1203 is a perspective view of the vicinity of the fixed chuck pin 30B. FIG. 13 is a diagram showing the vicinity of a movable chuck pin 50B in the substrate holding device SC of the substrate processing device 1A. In FIG. 13, reference numeral 1301 is a side view of the vicinity of the movable chuck pin 50B. Reference numeral 1302 is a side view of the vicinity of the movable chuck pin 50B, which is different from reference numeral 1301. Reference numeral 1303 is a perspective view of the vicinity of the movable chuck pin 50B.

The substrate processing device 1A differs from the substrate processing device 1 in that it includes an inert gas nozzle 67 instead of the back rinse nozzle 65, includes an inert gas supply part 68 instead of the back rinse supply part 66, and includes a plate (blocking plate) 25 and a plate drive part (blocking plate drive part) 26.

The plate 25 is configured to control the atmosphere of the space between the lower surface of the substrate W and the base part 20. The plate 25 is a disk-shaped member having an outer diameter larger than the diameter of the substrate W. The plate 25 is disposed so as to be positioned below the substrate W in a state held by the substrate holding device SC. The plate drive part 26 moves the plate 25 up and down. The plate drive part 26 may be, for example, a drive mechanism using magnetic force, but is not limited thereto. For example, the plate drive part 26 may be a drive mechanism using a motor or air cylinder etc.

An opening is formed at the center of the plate 25. The inert gas nozzle 67 is fitted into the opening and supplies inert gas between the substrate W and the plate 25. The inert gas supply part 68 supplies inert gas to the inert gas nozzle 67.

The substrate processing device 1A is configured for so-called BSRF (BackSide Rinse Free) processing. BSRF processing is a process that cleans only the non-device surface without cleaning the device surface of the substrate W with processing liquid. The non-device surface is the surface opposite to the device surface on which devices such as circuits are formed. In the substrate processing device 1A, the substrate holding device SC holds the substrate W such that the non-device surface becomes the upper surface. As described above, the substrate processing device 1A supplies processing liquid from above to clean the non-device surface of the substrate W.

According to the substrate processing device 1A, by supplying inert gas between the substrate W and the plate 25, adhesion of processing liquid mist to the lower surface of the substrate W can be effectively reduced. Such substrate processing device 1A also includes the substrate holding device SC, thereby reducing the possibility that processing liquid travels along the plurality of chuck pins (30A, 30B, 40A, 40B, 50A, 50B) and adheres to the device surface of the substrate W. Therefore, the possibility that processing liquid adheres to the device surface of the substrate W in BSRF processing can be further reduced.

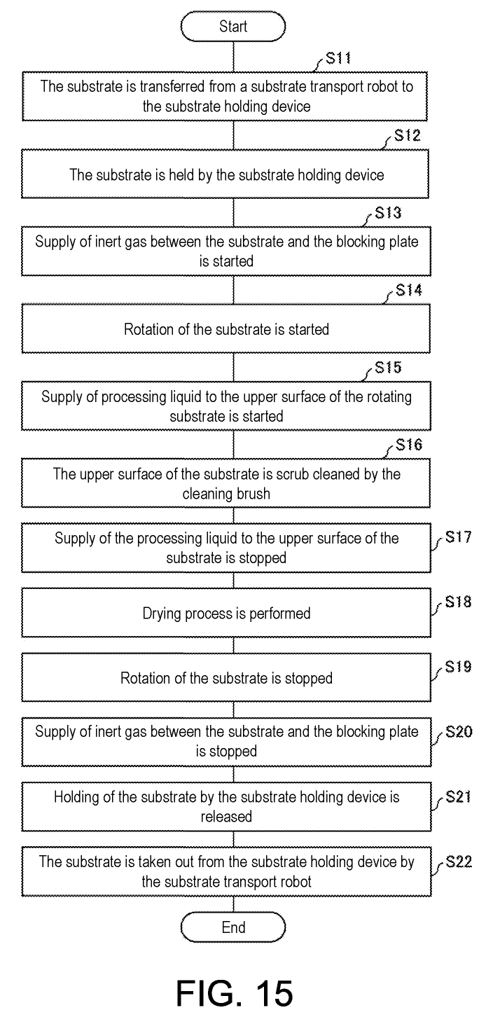

FIG. 15 is a flowchart showing one example of a substrate processing method by a substrate processing system equipped with the substrate processing device 1A. The configuration of the substrate processing system equipped with the substrate processing device 1A is the same as the substrate processing system 100, except that it is equipped with the substrate processing device 1A instead of the substrate processing device 1.

In the example shown in FIG. 15, first, similar to the example shown in FIG. 14, the substrate W is transferred from the substrate transport robot 111 to the substrate holding device SC (S11), and the substrate W is held by the substrate holding device SC (S12). In that state, in the example shown in FIG. 15, supply of inert gas between the substrate W and the plate 25 is started (S13), and thereafter rotation of the substrate W is started (S14).

Supply of processing liquid from the nozzle 71 to the upper surface of the rotating substrate W is started (S15). In that state, the upper surface of the substrate W is scrub cleaned by the cleaning brush 75 (S16). After completion of the scrub cleaning, supply of processing liquid to the upper surface of the substrate W is stopped (S17). Furthermore, by increasing the rotation speed of the base part 20 by the rotator 10, drying process of the substrate W is performed (S18).

After completion of the drying process, rotation of the substrate W is stopped (S19), supply of inert gas between the substrate W and the plate 25 is stopped (S20), and holding of the substrate W by the substrate holding device SC is released (S21). Thereafter, the substrate W is taken out from the substrate holding device SC by the substrate transport robot 111 (S22).

### Summary

A chuck pin according to one aspect of the disclosure is provided on a base part rotating around a reference axis extending in an up-down direction and holding a substrate that is disposed above the base part, the substrate being subjected to processing by a processing liquid, the chuck pin including: a main body part having a main surface at an upper portion; a lower surface support part that is provided to protrude upward from the main surface and that supports a lower surface of the substrate; and a side surface grip part that is provided to protrude upward from the main surface while being separated from the lower surface support part and that grips a side surface of the substrate.

Also, in the chuck pin according to one aspect of the disclosure, in a state of holding the substrate, a support position that is a position where the lower surface support part supports the substrate and a grip position that is a position where the side surface grip part grips the substrate are in different directions in plan view when viewed from the reference axis.

Also, in the chuck pin according to one aspect of the disclosure, the lower surface support part supports a region in a range of 0.1 mm to 0.6 mm from an end surface of the substrate on the lower surface of the substrate.

Also, in the chuck pin according to one aspect of the disclosure, the main body part further has a groove part provided between the lower surface support part and the side surface grip part, and the groove part is formed to be open radially outward when viewed from the reference axis in the main body part.

Also, in the chuck pin according to one aspect of the disclosure, the groove part is open in a direction that is outward in an angular range of 12 degrees or more and less than 90 degrees with respect to a tangential direction of the disk-shaped substrate in a direction opposite to a rotation direction of the base part, from a point between the lower surface support part and the side surface grip part in plan view.

Also, in the chuck pin according to one aspect of the disclosure, the side surface grip part includes a grip part that is a portion for gripping the substrate; and a non-grip part that is a region below the grip part, and the groove part is formed below the grip part and at least partially overlaps with the grip part in plan view.

Also, in the chuck pin according to one aspect of the disclosure, the lower surface support part includes a ridge part or a support surface for supporting the substrate, and supports the substrate at one point of the ridge part or the support surface, and the side surface grip part includes a grip surface for gripping the substrate, and supports an end surface of the substrate at one point or a linear region of the grip surface.

Also, in the chuck pin according to one aspect of the disclosure, an angle of the ridge part or the support surface in the lower surface support part with respect to a horizontal plane is 26 degrees to 33 degrees.

Also, a substrate holding device according to one aspect of the disclosure includes: a base part provided rotatably around a reference axis extending in an up-down direction; a rotator that rotates the base part around the reference axis; and any one of the above chuck pins attached to the base part, and a chuck pin drive part. At least one of the chuck pins among the plurality of chuck pins is rotatably attached to the base part around a pin shaft parallel to the reference axis, and the chuck pin drive part is configured to be capable of switching the chuck pin between a holding state in which the chuck pin contacts an outer edge of the substrate to hold the substrate and a release state in which the chuck pin is capable of being separated from the outer edge of the substrate, by rotating the rotatable chuck pin around the pin shaft.

Also, a substrate processing device according to one aspect of the disclosure includes the above substrate holding device; a nozzle that discharges a processing liquid to the substrate held by the substrate holding device; and a processing liquid supply part that supplies the processing liquid to the nozzle.

What is claimed is:

1. A chuck pin, provided on a base part rotating around a reference axis extending in an up-down direction and holding a substrate that is disposed above the base part, the substrate being subjected to processing by a processing liquid, the check pin comprising:
a main body part having a main surface at an upper portion;
a lower surface support part that is provided to protrude upward from the main surface and that supports a lower surface of the substrate; and
a side surface grip part that is provided to protrude upward from the main surface while being separated from the lower surface support part and that grips a side surface of the substrate.

2. The chuck pin according to claim 1, wherein in a state of holding the substrate, a support position that is a position where the lower surface support part supports the substrate and a grip position that is a position where the side surface grip part grips the substrate are in different directions in plan view when viewed from the reference axis.

3. The chuck pin according to claim 2, wherein the lower surface support part supports a region in a range of 0.1 mm to 0.6 mm from an end surface of the substrate on the lower surface of the substrate.

4. The chuck pin according to claim 1,
wherein the main body part further has a groove part provided between the lower surface support part and the side surface grip part, and
the groove part is formed to be open radially outward when viewed from the reference axis in the main body part.

5. The chuck pin according to claim 4, wherein the groove part is open in a direction that is outward in an angular range of 12 degrees or more and less than 90 degrees with respect to a tangential direction of the disk-shaped substrate in a direction opposite to a rotation direction of the base part, from a point between the lower surface support part and the side surface grip part in plan view.

6. The chuck pin according to claim 5,
wherein the side surface grip part comprises:
a grip part that is a portion for gripping the substrate; and
a non-grip part that is a region below the grip part, and
the groove part is formed below the grip part and at least partially overlaps with the grip part in plan view.

7. The chuck pin according to claim 1,
wherein the lower surface support part comprises a ridge part or a support surface for supporting the substrate, and supports the substrate at one point of the ridge part or the support surface, and
the side surface grip part comprises a grip surface for gripping the substrate, and supports an end surface of the substrate at one point or a linear region of the grip surface.

8. The chuck pin according to claim 7,
wherein an angle of the ridge part or the support surface in the lower surface support part with respect to a horizontal plane is 26 degrees to 33 degrees.

9. A substrate holding device, comprising:
a base part provided rotatably around a reference axis extending in an up-down direction;
a rotator that rotates the base part around the reference axis;
a plurality of chuck pins according to claim 1 attached to the base part; and
a chuck pin drive part,
wherein at least one of the chuck pins among the plurality of chuck pins is rotatably attached to the base part around a pin shaft parallel to the reference axis, and
the chuck pin drive part is configured to be capable of switching the chuck pin between a holding state in which the chuck pin contacts an outer edge of the substrate to hold the substrate and a release state in which the chuck pin is capable of being separated from the outer edge of the substrate, by rotating the rotatable chuck pin around the pin shaft.

10. A substrate processing device, comprising:
the substrate holding device according to claim 9;
a nozzle that discharges a processing liquid to the substrate held by the substrate holding device; and
a processing liquid supply part that supplies the processing liquid to the nozzle.
